(19) United States
(12) Patent Application Publication
(10) Pub. No.: US 2013/0000688 A1
(43) Pub. Date: Jan. 3, 2013

(54) THERMOELECTRIC DEVICE

(76) Inventors: Hans S. Cho, Palo Alto, CA (US); Alexandre M. Bratkovski, Mountain View, CA (US); Theodore I. Kamins, Palo Alto, CA (US)

(21) Appl. No.: 13/387,015

(22) PCT Filed: Mar. 23, 2010
(86) PCT No.: PCT/US10/28354

§ 371 Date: Jan. 25, 2012

(51) Int. Cl. H01L 35/28; H01L 35/34; B82Y 99/00

(52) U.S. Cl. 136/200; 438/54; 136/201; 257/E21.506; 977/948

(57) ABSTRACT

A thermoelectric device (100) includes a pair of spaced apart oppositely doped structures (110, 120) connecting between a common electrode (140) at a first end and different ones of a pair (150) of separate electrodes (150a, 150b) at a second end of the structures. Each oppositely doped structure includes a first material (112, 122) of a respectively doped semiconductor bounded by a second material (114, 124, 116, 126). Boundaries (111, 121) between the respective first and second materials are parallel to a charge carrier conduction path between the common electrode and the separate electrodes. The respectively doped semiconductor has a thickness configured to be less than a phonon scattering length.

### CROSS-REFERENCE TO RELATED APPLICATIONS

N/A

### STATEMENT REGARDING FEDERALLY SPONSORED RESEARCH OR DEVELOPMENT

N/A

### BACKGROUND

Thermoelectric devices based on the thermoelectric or Seebeck-Peltier effect may be used to either convert a temperature difference into electric power or produce a temperature difference from electric power. In particular, a thermoelectric device may be employed to extract energy from a temperature difference (Seebeck effect) between a first or ‘hot’ body or mass and a second or ‘cold’ body or mass. The extracted energy is converted into an electric voltage and current that may subsequently provide power to a circuit external to the thermoelectric device, for example. Conversely, when electric power is applied or provided to the thermoelectric device, heat is transported from one side to another of the thermoelectric device (Peltier effect). When provided with electric power from an external source, the thermoelectric device may be used to create a thermal difference between the first mass and the second mass. The efficiency of thermoelectric devices is ultimately dependent on reducing passive thermal conductivity (e.g., via phonons or phonon conduction) through the device while maintaining a high electrical conductivity associated with carriers (e.g., holes and/or electrons) responsible for providing the thermoelectric characteristics of the thermoelectric device. Unfortunately, many thermoelectric devices typically exhibit a relatively low efficiency.

Improving efficiency of thermoelectric devices often focuses on material selection. While some materials may inherently possess desirably high electrical conductivity concomitant with low thermal conductivity, efforts to either increase the electrical conductivity or reduce the thermal conductivity (or both) of specific materials or material combinations is often a complex task. For example, material and structural modifications have been pursued to induce phonon scattering to reduce thermal conductivity while simultaneously maintaining reasonable electrical conductivity levels. In general, such exemplary efforts have yet to provide a thermoelectric device that is sufficiently efficient, while also possibly being commercially viable and cost effective.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1 illustrates a side view of a portion of a thermoelectric device, according to an embodiment of the present invention.

FIG. 2 illustrates a perspective view of a thermoelectric device including a cut out exposing a cross section of a portion of a structure, according to an embodiment of the present invention.

FIG. 3 illustrates a perspective view of the thermoelectric device including a cut out exposing a cross section of a portion of a structure, according to another embodiment of the present invention.

FIGS. 4A illustrates a cross sectional top view of a portion of a thermoelectric structure, according to an embodiment of the present invention.

FIGS. 4B illustrates a perspective cross sectional view of a portion of a thermoelectric structure, according to another embodiment of the present invention.

FIG. 5 illustrates a side view of a thermoelectric system, according to an embodiment of the present invention.

FIG. 6 illustrates a flow chart of a method of making a thermoelectric device, according to an embodiment of the present invention.

Certain embodiments of the present invention have other features that are one of in addition to and in lieu of the features illustrated in the above-referenced figures. These and other features of the invention are detailed below with reference to the preceding drawings.

### DETAILED DESCRIPTION

Embodiments of the present invention are directed to a thermoelectric device that scatters phonons while conducting charge carriers (e.g., one or both of electrons and holes) along a charge carrier conduction path. The thermoelectric device includes a p-type structure and an n-type structure connected between a common electrode and different ones of a pair of separate electrodes. Each of the p-type and n-type structures comprises a plurality of layers of different materials that define boundaries or interfaces between the different materials. The boundaries are parallel to the charge carrier conduction path between the electrodes. A first material of the plurality is a respectively doped semiconductor material having high carrier conductivity that is bounded by a second, different material on at least one side. A thickness of the first material is less than a phonon scattering length. As such, the thickness of the first material substantially limits phonon (thermal) conduction through the respectively doped structure while charge carrier conduction is relatively unaffected thereby. In particular, the thickness of the first material is smaller than a width that is approximately equivalent to a mean free path of phonons and is larger than a width that is approximately equivalent to a mean free path of electrons and holes.

The mean free path of phonons may be defined as an average distance traveled by the phonons between collisions. The average distance traveled is dependent in part upon the material in which or through which the phonons are traveling. The average distance traveled between collisions is further dependent on a temperature of the material, i.e., the temperature at which the mean free path of phonons is determined. Likewise, the mean free path of one or both of electrons and holes (hereinafter ‘charge carriers’) may be defined as an average distance traveled by the charge carriers between collisions. The average distance traveled by the charge carriers between collisions is dependent in part upon the material that the charge carriers are traveling in or through. The average distance traveled between collisions of the charge carriers is also further dependent on a temperature of the material, i.e., the temperature at which the mean free path of the charge carriers is determined.

For most materials (and most temperatures) of interest to the embodiments of the present invention herein, the mean free path of charge carriers is smaller than the mean free path of phonons. As such, according to the present embodiments, ultra thin films or cores of at least the first material having a thickness or core diameter that is less than a phonon scattering length will increase phonon scattering and suppress phonon conduction along the parallel conduction paths in the thermoelectric device herein, while having relatively less impact on the charge carrier conduction along the parallel paths. The phonon conduction suppression will reduce thermal conductivity while leaving the electrical conductivity relatively unaffected. Reduced thermal conductivity in the thermoelectric device embodiments also increases efficiency of the device since thermal conductivity decreases at a greater rate than electrical conductivity as the lateral dimensions are reduced. For example, efficiency of a thermoelectric device is measured in terms of the dimensionless figure of merit ZT defined by ZT=(S²·σ/κ)·T, where S is thermoelectric power (Seebeck coefficient), (σ) is the electrical conductivity, (κ) is the thermal conductivity, and T is the temperature of the thermoelectric device. Therefore, an incremental decrease in the thermal conductivity (κ) according to the embodiments herein will incrementally increase the figure of merit ZT and therefore increase the efficiency of the thermoelectric device. The terms ‘conductivity’ and ‘conductance’ are used interchangeably herein even though bulk properties of a material may not be changed in accordance with the embodiments of the invention.

In some embodiments of the present invention, a thermoelectric device is provided. In other embodiments, a thermoelectric system that includes a plurality of thermoelectric devices is provided. In still other embodiments, a method of making a thermoelectric device is provided.

In some embodiments, the thermoelectric device comprises a pair of spaced apart, elongated, oppositely doped structures that connect between a common electrode at one end of the structures and different ones of a pair of separate electrodes at an opposite end of the structures. The separate electrodes of the pair are spaced apart but adjacent to one another in the same plane. The elongated, oppositely doped structures define a charge carrier conduction path between the common electrode and the respective separate electrodes. Moreover, the elongated oppositely doped structures define a phonon conduction path between the common electrode and the respective separate electrodes.

Each structure of the oppositely doped pair comprises a first material that is a respectively doped semiconductor material bounded by a second material on at least one side. The second material is another material that is different from the first material such that boundaries between the different materials are formed when placed adjacent to one another. For example, a boundary delineates a change in a lattice between the first material and the second material. In accordance with the present embodiments herein, the boundaries between the different materials of the respective structures are parallel to the charge carrier conduction path between the common electrode and the respective separate electrodes. Moreover according to the present embodiments, the respectively doped semiconductor first material has a thickness configured to be less than a phonon scattering length along the charge carrier conduction path.

By ‘oppositely doped’ structure, it is meant that a first structure of the pair of oppositely doped structures is a p-type structure that comprises a p-type semiconductor material as the first material and further that a second structure of the pair of oppositely doped structures is an n-type structure that comprises an n-type semiconductor material as the first material. By ‘respectively doped’ semiconductor, it is meant that the semiconductor material is doped consistent with being a part of the p-type structure or the n-type structure. By ‘second material’ it is meant a material that is different from the first material in one or both of composition and crystallinity. For example, a different composition means that the second material may be one of an insulator material and another semiconductor material different from the first semiconductor material. Another semiconductor material includes within its scope, but is not limited to, a semiconductor alloy or a compound semiconductor that comprises one or more other semiconductor materials and that may also comprise the first semiconductor material. A different crystallinity means that the second material may be a semiconductor of the same composition as the first material, but has different crystal content or structure from the first material. For example, the second material may be an amorphous or polycrystalline semiconductor when the first material is a single crystal semiconductor. The term ‘another material’ may mean the second material, as defined above, a third material that differs from both the first material and the second material, a fourth material that differs from the first, second and third materials, and so on.

In some embodiments, the second material in each structure of the pair of oppositely doped structures independently includes, but is not limited to, a different semiconductor material from the respective semiconductor first material or an insulator material. The second material bounds the first material on at least one side or at least two sides, or surrounds the first material, depending on the embodiment. In some embodiments, the second material of a structure is an insulator material, such as an oxide, carbide or nitride of a semiconductor material for example. In other embodiments, the second material of a structure is a different semiconductor material relative to the first material. The different semiconductor material is also similarly doped relative to the respectively doped semiconductor of the first material. By ‘similarly doped’ it is meant that the semiconductor second material comprises the same doping type as the respectively doped semiconductor first material; however, the amount of doping (dopant concentration) in the semiconductor second material may be either the same as or different from the semiconductor first material. Moreover, the similarly doped semiconductor second material has a thickness dimension that is also configured to be less than a phonon scattering length along the conduction path but larger than a charge carrier scattering length.

In some embodiments, the first material and the second material of a respective oppositely doped structure are provided as adjacent planar layers stacked together (e.g., stacked on top of one another). In some embodiments, the planar layers of the respectively doped semiconductor first materials are continuous, ultra-thin films. In some embodiments, the first material planar layer and the second material planar layer alternate regularly every other one. For example, first material layers of respectively doped polycrystalline silicon may alternate with second material layers of similarly doped amorphous silicon. In another example, first material layers of respectively doped silicon may alternate with second material layers of silicon dioxide. In other embodiments, there are more than one different material layers, and adjacent planar layers of the different materials alternate on opposite sides of the first material either regularly or irregularly in a stack. For example, first material layers of respectively doped silicon may alternate irregularly with second material layers of silicon dioxide and third material layers of similarly doped germanium.

In some embodiments, the respectively doped semiconductor first material layer comprises spaced apart, elongated stripes supported by a continuous layer of the second material or another material, for example an insulator material layer. The elongated stripes of the first material extend from the common electrode to the respective separate electrode of the pair. In some of these embodiments, in addition to the thickness, the elongated stripes of the respectively doped semiconductor first material may have a width also configured to be less than a phonon scattering length but larger than the charge carrier conduction path.

In some embodiments, the respectively doped semiconductor first material is provided as a nanowire core and the second material is an adjacent concentric layer of another material that substantially surrounds the nanowire core along its length as a shell layer in a core-shell nanowire. At least the nanowire core has a thickness (or a diameter) that is less than a phonon scattering length but larger than a charge carrier scattering length. In some embodiments, if the second material is another semiconductor material, it is similarly doped to the first material, and a thickness of the concentric shell layer also is similarly less than a phonon scattering length but larger than a charge carrier scattering length. In other embodiments, if the second material is an insulator material, e.g., SiO₂, the thickness of the second material shell layer need not be less than a phonon scattering length to scatter phonons. In this embodiment, the presence of a semiconductor-insulator interface (between the core-shell) will sufficiently scatter phonons in the nanowire core.

In some embodiments, a third material surrounds the second material layer as a concentric layer of another material. As such, the core-shell nanowire comprises a first material core of the respectively doped semiconductor, a second material intermediate shell layer and a third material outer shell layer of another material. In some of these embodiments, the third material of the outer shell layer is either the first material alternating with the second material or another material that is different from both the second material intermediate shell layer and the first material core. The first, second and third materials may differ in one or both of composition and crystallinity (e.g., to provide different coaxial lattice layers) depending on the embodiment. For example, the first material nanowire core may be single crystal silicon, the intermediate shell second material layer may be amorphous silicon and the outer shell third material layer may be polycrystalline silicon and still be within the scope of the present embodiments. In another example, the first material nanowire core may be single crystal silicon, the intermediate shell second material layer may be polycrystalline germanium and the outer shell third material layer may be polycrystalline silicon.

In some embodiments, the first material of the respectively doped semiconductor herein independently may include, but is not limited to, a relatively thermally conductive semiconductor from Group IV, a Group III-V compound semiconductor, and a Group II-VI compound semiconductor. Moreover, as mentioned above, the semiconductor materials independently may be one of single crystal, polycrystalline and amorphous, for example. As described above, the second and respective other materials (e.g., the third material) may be another or different semiconductor material, taken from the list above, an alloy of any of the above semiconductors, or an insulator material including, but not limited to, an oxide, carbide or nitride of a semiconductor or a metal. For example, the second or other material(s) may be silicon dioxide, silicon nitride or alumina, for example. The above-listed semiconductor first materials have a characteristic thickness that ranges from about 1 nanometer (nm) to less than about 100 nm to scatter phonons, for example, for a broad range of temperatures that accommodates a plurality of device applications. For example, the broad temperature range for structures comprising silicon or a silicon-germanium alloy might be from room temperature to room temperature plus 400 degrees Kelvin. Herein, a ‘characteristic thickness’ is a thickness of a material layer that is less than the phonon scattering length but greater than the charge carrier scattering length for the material.

The respectively doped semiconductor first materials are moderately to heavily doped with either a p-type doping or an n-type doping. Moderate to heavy doping provides high carrier conductivity to the respective structure of the oppositely doped pair of structures. The high carrier conductivity facilitates charge carrier conduction along the parallel conduction path.

As used herein, the article ‘a’ is intended to have its ordinary meaning in the patent arts, namely ‘one or more’. For example, ‘a material’ means one or more materials and as such, ‘the material’ explicitly means ‘the material(s)’ herein. Likewise, ‘another material’ means one or more ‘other’ materials and as such ‘the other material’ explicitly means ‘the other material(s)’. Also, any reference herein to ‘top’, ‘bottom’, ‘upper’, ‘lower’, ‘up’, ‘down’, ‘front’, back’, ‘left’ or ‘right’ is not intended to be a limitation herein. Herein, the term ‘about’ when applied to a value generally means plus or minus 10% unless otherwise expressly specified. Moreover, examples herein are intended to be illustrative only and are presented for discussion purposes and not by way of limitation.

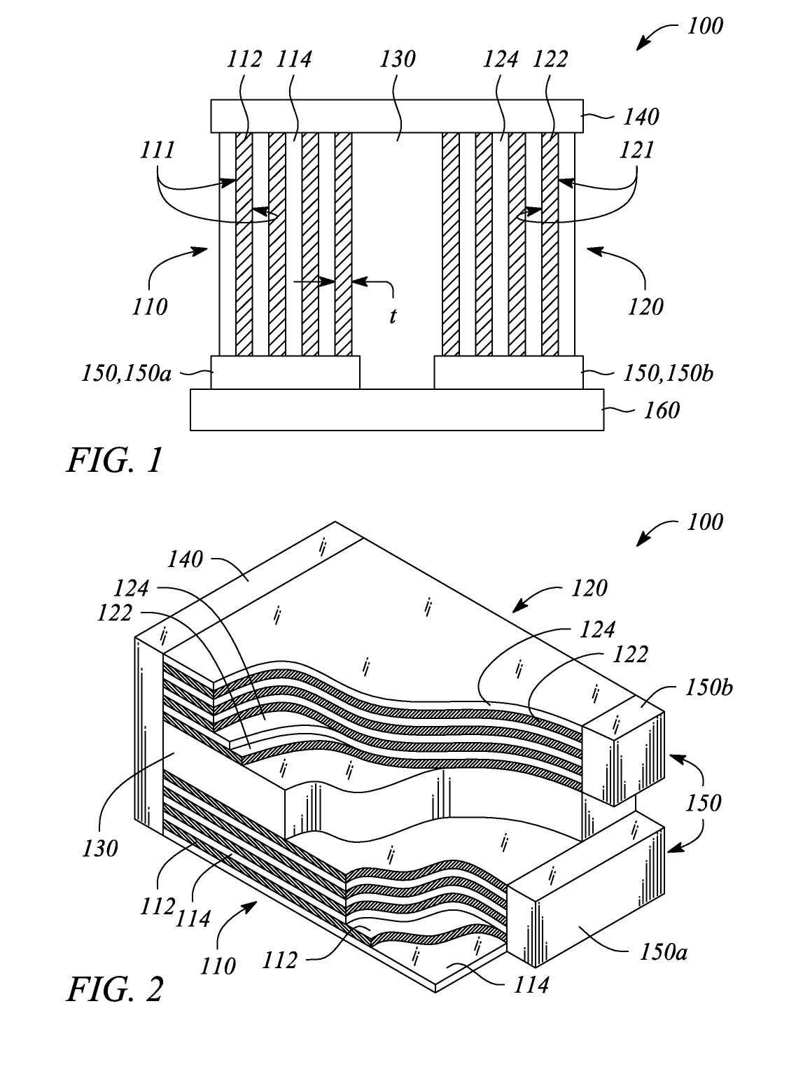

FIG. 1 illustrates a cross sectional side view of a portion of a thermoelectric device (100), according to an embodiment of the present invention. The thermoelectric device (100) comprises a pair of oppositely doped structures (110, 120). In the illustrated embodiment, the oppositely doped structures (110, 120) are separated by a space (130). In some embodiments, the space (130) comprises an insulator spacer material (which may also be referred to as reference number (130) herein). The thermoelectric device (100) further comprises a common electrode (140) and a pair (150) of separate electrodes (150a, 150b). In the illustrated embodiment, the separate electrode pair is supported by a substrate (160) by way of example. Each oppositely doped structure (110, 120) is connected to the common electrode (140) at one end of the respective structure (110, 120). An opposite end of the first structure (110) is connected to a first separate electrode (150a) of the electrode pair (150). Moreover, an opposite end of the second structure (120) is connected to a second separate electrode (150b) of the electrode pair (150). The separate electrodes (150a, 150b) are spaced apart in the same plane. Each oppositely doped structure (110, 120) of the thermoelectric device (100) comprises adjacent layers of different materials. Boundaries (111, 121) between the adjacent material layers are parallel to a charge carrier conduction path through the structures between the common electrode (140) and the pair (150) of separate electrodes.

FIG. 2 illustrates a perspective view of a thermoelectric device (100), according to an embodiment of the present invention, which includes a cut out to show a cross section of the oppositely doped structures. The illustrated embodiment has adjacent planar layers in a stacked construction, according to this embodiment. A first structure (110) comprises a first material layer (112) of a semiconductor material having an exemplary p-type doping alternating with a second material layer (114). The second material layer (114) may be another p-type semiconductor material different from the first semiconductor material layer (112) or may be an insulator material, as described above, for example. A second structure (120) comprises another first material layer (122) of a semiconductor material having an exemplary n-type doping alternating with another second material layer (124). The other second material layer (124) may be another n-type semiconductor material different from the other first semiconductor material (122) or an insulator material, also described above, for example.

In some embodiments, the first semiconductor material layer (112) of the first structure (110) and the other first semiconductor material layer (122) of the second structure (120) are different semiconductor materials as well as having opposite or reverse doping. In other embodiments, the first semiconductor material layer (112) of the first structure (110) and the other first semiconductor material layer (122) of the second structure (120) are the same or substantially similar semiconductor materials. Independent of the first semiconductor material layers (112, 122) of the oppositely doped structures (110, 120), in some embodiments, the second material layer (114) of the first structure (110) and the other second material layer (124) of the second structure (120) are different materials. In other embodiments, the second material layer (114) of the first structure (110) and the other second material layer (124) of the second structure (120) are the same.

In some embodiments, one or both of the first structure (110) and the second structure (120) may further comprise a planar layer of a third material (not specifically illustrated in FIG. 2). The third material layer may alternate regularly or irregularly with the first material layer and the second material layer of the respective structure (110, 120), depending on the embodiment. Moreover, although not illustrated, the number of planar layers in the first structure (110) may differ from the number of planar layers in the second structure (120). The number of respectively doped semiconductor layers (112, 122) in a respective structure (110, 120) of the thermoelectric device (100) may facilitate scaling of power generated by the thermoelectric device (100), for example. As such, the thermoelectric device (100) may be configured for a variety of physical situations, depending on the embodiment, for example situations including, but not limited to, a form factor for an area covered by the device or a mode of use, e.g., cooling or voltage harvesting.

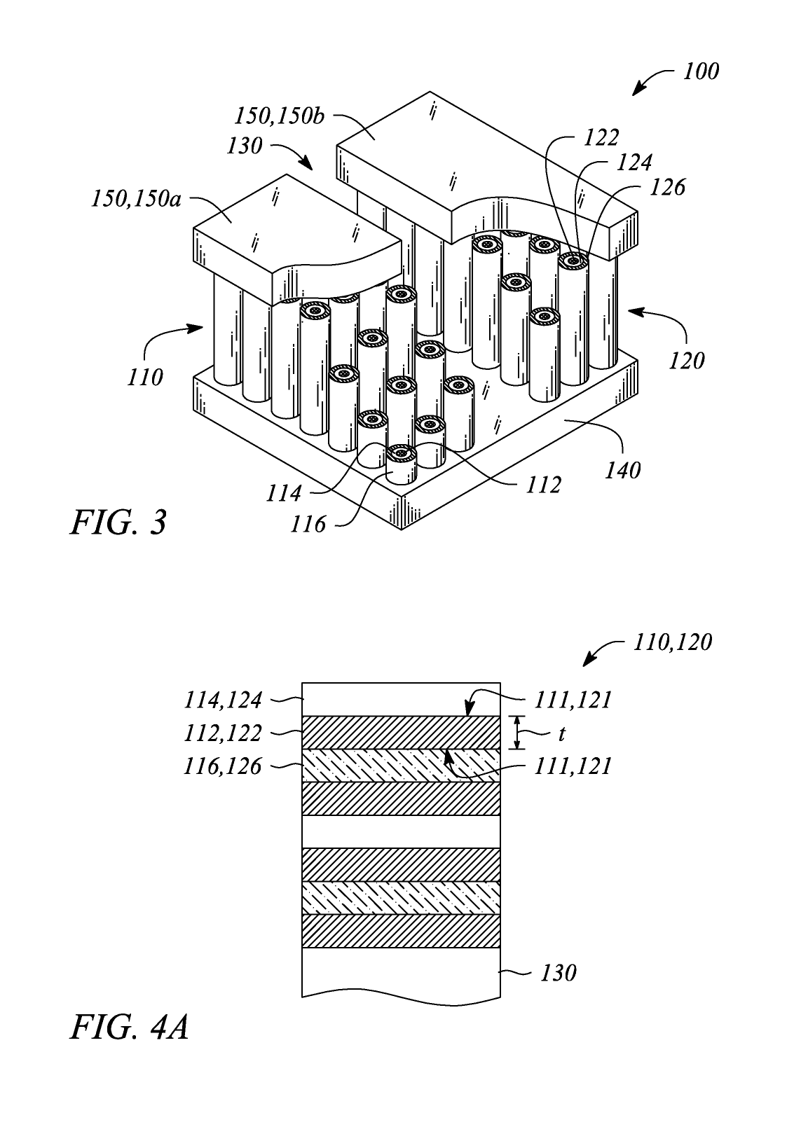

FIG. 3 illustrates a perspective view of a thermoelectric device (100), according to another embodiment of the present invention, which includes a cut out to show a cross section of the oppositely doped structures. In the illustrated embodiment, the adjacent layers are concentric having a coaxial construction of core-shell nanowires. In particular, as illustrated in FIG. 3, the first structure (110) of the oppositely doped structures (110, 120) comprises a first plurality of core-shell nanowires spaced apart (130) from the second structure (120) comprising a second plurality of core-shell nanowires. The respective pluralities of core-shell nanowires extend between the common electrode (140) at one end (e.g., a bottom end) and different ones of the pair 150 of separate electrodes (150a, 150b) at an opposite end (e.g., a top end). Each core-shell nanowire of the respective structures (110, 120) comprises the first semiconductor material layer (112, 122) having a respective p-type doping or an n-type doping as a nanowire core (112, 122). Each core-shell nanowire of the respective structures (110, 120) further comprises the second material layer (114, 124) as a concentric layer surrounding the core layer (112, 122). The second material layer (114, 124) may be a respectively doped semiconductor material that is different from the first semiconductor material of the core (112, 122) or may be an insulator material. In some embodiments, as illustrated in FIG. 3 by way of example, each core-shell nanowire of the respective structures (110, 120) may further comprise a third material layer (116, 126) as a concentric layer surrounding the second material layer (114, 124).

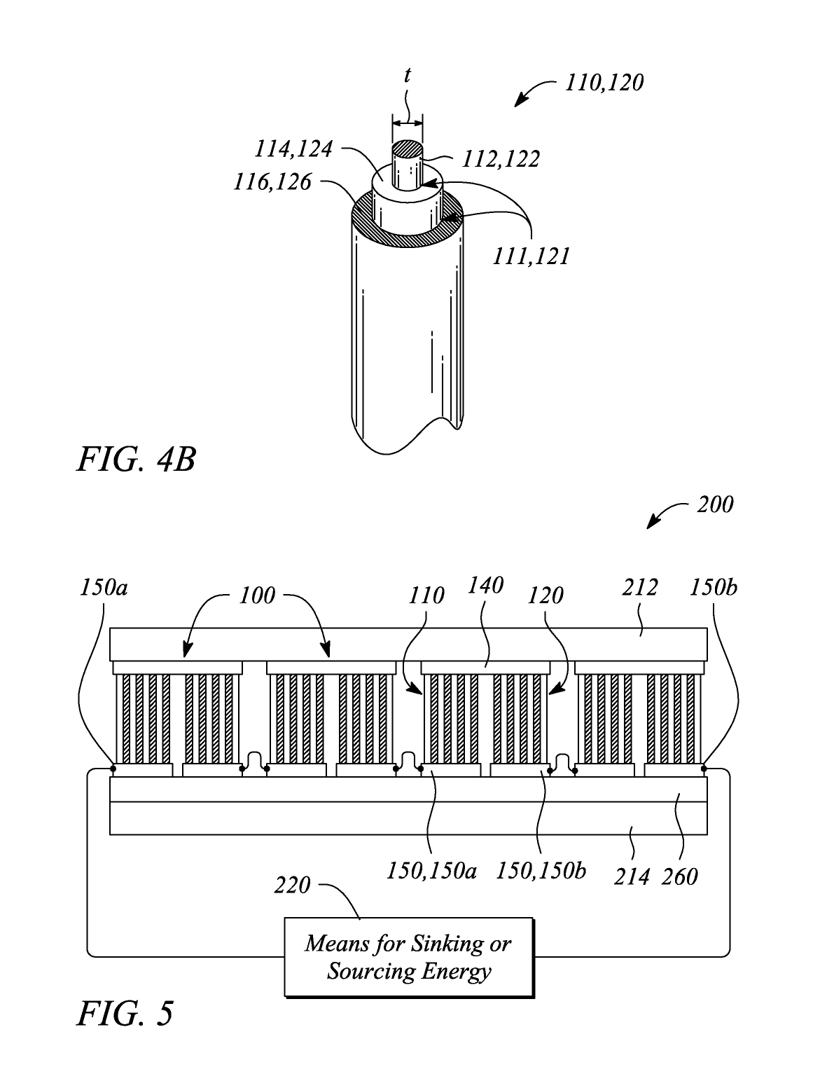

FIG. 4A illustrates a cross sectional end view of a representative stack of planar layers of an exemplary structure (110, 120), according to an embodiment of the present invention. Four planar layers of the respectively doped semiconductor first material layer (112, 122) are illustrated along with two alternating planar layers of the second material (114, 124) and two alternating layers of a third material (116, 126), by way of example. Also illustrated is a portion of the insulator material spacer (130) that separates the respective oppositely doped structures (110, 120). Corresponding boundaries (111, 121) between different material layers and the characteristic thickness (t) of the respectively doped semiconductor first material layer (112, 122) are further illustrated.

FIG. 4B illustrates a perspective cross sectional view of a representative core-shell nanowire of an exemplary structure (110, 120), according to another embodiment of the present invention. In particular, an end of the core-shell nanowire is illustrated in a manner that exposes an internal structure (i.e., an exploded view) at a top end. The respectively doped semiconductor first material (112, 122) is the nanowire core (112, 122) having a characteristic thickness or diameter (t). The second material layer (114, 124) is a concentric intermediate shell layer (114, 124). Further illustrated in the embodiment of FIG. 4B is that the core-shell nanowire may further comprise a concentric layer of the third material (116, 126) as an outer shell layer (116, 126). The outer shell layer (116, 126) is representative of another material layer that may be the same as the material of the nanowire core (112, 122) or may be a material different from both the materials of the nanowire core (112, 122) and the intermediate shell (114, 124). Each of the second material concentric layer (114, 124) and third material concentric layer (116, 126) has a radial thickness that may or may not be within the characteristic thickness (t) range, depending on the embodiment. For example, each of the concentric layers (112, 122, 114, 124 as well as 116 and 126, if present) may have a radial thickness (t) that is less than a phonon scattering length (i.e., the characteristic thickness) for a respectively doped semiconductor material of the respective layer. However, if one or both of the second and third concentric layers is an insulator material, the insulator concentric layer(s) may be thicker than the characteristic thickness (t).

According to the various embodiments herein, the different material layers (112, 114. 116; 122, 124, 126) of the oppositely doped structures (110, 120) have distinct interfaces or boundaries (111, 121) between the adjacent different materials. As mentioned above, the boundaries (111, 121) are parallel to a charge carrier conduction path through the structures (110, 120). Moreover, the boundaries (111, 121) are also parallel to a phonon scattering path between the common electrode (140) and the pair (150) of separate electrodes (150a, 150b). The boundaries (111, 121) delineate a thickness dimension of the different material layers whether in planar layers (e.g., FIG. 4A) or in concentric layers (e.g., FIG. 4B). In some embodiments (as illustrated), the boundaries (111, 121) extend from one end of the layers to the opposite end between the common electrode (140) and the pair (150) of separate electrodes (150a, 150b). In other embodiments (not illustrated), some boundaries extend only for a portion of the distance between respective electrodes to delineate a low thermal conductance region in the structure.

At least the respectively doped semiconductor first material layer (112) of the first structure (110) and the respectively doped semiconductor first material layer (122) of the second structure (120) have the characteristic thickness (t) that is configured to be greater than a charge carrier scattering length so that charge carriers move relatively freely between the common electrode (140) and the respective separate electrodes (150a, 150b) along the first material layers. Moreover, the characteristic thickness (t) of the respectively doped semiconductor first material layers (112, 122) is narrower than the approximate average mean free path length of phonons (i.e., phonon scattering length) in order to increase phonon scattering along the charge carrier conduction path. With respect to the core-shell nanowire embodiment in FIG. 4B, the thickness dimension (t) includes within its scope a diameter of the nanowire core (112, 122) of the respectively doped semiconductor first material, and in some embodiments, of a radial thickness of a respective shell layer of one or both of the second material (114, 116) and the third material (124, 126).

In some embodiments, a width of the space (130) between the first structure (110) and the second structure (120) is configured to diminish electrical interference between the oppositely doped structures (110, 120). In some embodiments, the width of the space (130) is configured to prevent any electrical interference between the oppositely doped structures (110, 120). Moreover, the separate electrodes (150a, 150b) are spaced apart to avoid direct electrical conduction or ‘electrical shorting’ between the oppositely doped structures (110, 120), for example. In some embodiments, the spacing between the separate electrode pair (150) is similar to the space (130) between the oppositely doped structures (110, 120) described above. In the various embodiments herein, the space (130) is relatively macro-scale compared to the thickness of each oppositely doped structure (110, 120) to facilitate assembly of the oppositely doped structures (110, 120) to the pair (150) of electrodes during manufacturing of the thermoelectric device (100).

In some embodiments, the layers of the respectively doped semiconductor first material (112, 122) each have a characteristic thickness (t) of less than 100 nanometers (nm). In some embodiments, the characteristic thickness (t) is less than 50 nm. In still other embodiments, the characteristic thickness (t) is less than 10 nm. In some embodiments, the second material layers (114, 124) and other material layers (e.g., third material layers (116, 126)) have a thickness less than about 100 nm. In some embodiments, the second material layers (114, 124) and other material layers (e.g., third material layers (116, 126)) have a characteristic thickness ranging from about 10 nm to under 100 nm. In some embodiments, the thickness of one or both of the second material layers (114, 124) and the other material layers (116, 126) may be substantially the same as the respectively doped semiconductor first material layers (112, 122). Moreover, depending on the embodiment, the width of the space (130) or thickness of the insulator spacer material (130) may be one to several orders of magnitude or more larger than the characteristic thickness (t).

FIG. 5 illustrates a side view of a thermoelectric system (200) according to an embodiment of the present invention. The thermoelectric system (200) comprises a plurality of pairs (100) of layered structures. Four pairs of layered structures are illustrated in FIG. 5 by way of example. Each pair (100) of layered structures includes a common electrode (140) at one end and a pair (150) of separate electrodes at an opposite end. The pairs (100) of layered structures are substantially similar to the thermoelectric devices (100) according to any of the embodiments described above and are referred to as such herein for simplicity of discussion.

The separate electrode pairs (150) of the plurality of thermoelectric devices (100) may be supported on a substrate (260), as illustrated in FIG. 5 by way of example. One of the separate electrodes (e.g., 150a) provides a p-terminal (i.e., is connected to a p-type doped structure) and the other separate electrode (e.g., 150b) provides an n-terminal (i.e., is connected to an n-type doped structure) to each thermoelectric device (100) of the system (200).

The individual thermoelectric devices (100) may be connected to one another in either a series configuration (as illustrated by way of example in FIG. 5) or a parallel configuration (not illustrated), depending on the embodiment of the thermoelectric system (200). In the illustrated embodiment, the n-terminal of a first thermoelectric device (100) of the plurality is connected in series to the p-terminal of a second thermoelectric device (100) of the plurality, the n-terminal of the second thermoelectric device (100) is connected in series to the p-terminal of a third thermoelectric device (100) of the plurality, and so on, for example, to connect together the thermoelectric devices (100) of the plurality. In other embodiments (not illustrated), the p-terminals of individual thermoelectric devices of the plurality are connected in parallel to one another and the n-terminals of the individual thermoelectric devices of the plurality are connected in parallel to one another in the thermoelectric system.

The thermoelectric system (200) further comprises a first mass (212) and a second mass (214). In some embodiments, the first mass (212) may be at a first temperature while the second mass (213) is at a second temperature. In some embodiments, the second temperature may be lower than the first temperature (cold mass'). For example, the first mass (212) may be a ‘hot mass’ or a ‘hot body’ while the second mass (214) may be a relatively cooler mass (e.g., ‘cold mass’ or ‘cold body’).

One of the first mass (212) and the second mass (214) is adjacent to the common electrode (140). For example, one of the first and second masses (212, 214) may be adjacent to a side of the common electrode (140) that is opposite to where the pairs of oppositely doped structures of the plurality of thermoelectric devices (100) connect to the common electrode (140). A different one of the first mass (212) and the second mass (214) is adjacent to the pairs (150) of separate electrodes, or the substrate (260), if present. For example, the different one of the first and second masses (212, 214) may be adjacent to a side of the substrate (260) that is opposite to where the pairs (150) of separate electrodes of the plurality of thermoelectric devices (100) are attached.

The thermoelectric system (200) further comprises means (220) for sinking or sourcing energy connected between the pairs (150) of separate electrodes of the plurality of thermoelectric devices (100). The means (220) for sinking or sourcing energy comprises one of a voltage source (or current source) and a resistive circuit, depending on the embodiment. For example, when the thermoelectric system (200) is configured to dissipate heat (e.g., to cool the first mass (212) by transporting heat to the second mass (214)), the means (220) for sinking or sourcing energy comprises a voltage source (i.e., means (220) for sourcing energy). In some embodiments, the voltage source (220) is connected between a p-terminal of a first thermoelectric device (100) and an n-terminal of an N-th thermoelectric device (100) where the plurality of devices (100) is connected in series in the thermoelectric system (200), as illustrated in FIG. 5. In other embodiments (not illustrated), the voltage source is connected between parallel-connected p-terminals and parallel-connected n-terminals of the thermoelectric devices of the thermoelectric system.

In another example, when the thermoelectric system (200) is configured to generate power (e.g., to convert heat energy from the first mass (212) to electricity adjacent to the second mass (214)), the means (220) for sinking or sourcing energy comprises a resistive circuit (i.e., means (220) for sinking energy). In some embodiments, the resistive circuit (220) is connected between the p-terminal of a first thermoelectric device (100) and the n-terminal of an N-th thermoelectric device (100) of the series connected thermoelectric devices (100) of the thermoelectric system (200), as illustrated in FIG. 5. In other embodiments (not illustrated), the thermoelectric devices of the plurality are connected in parallel and the resistive circuit is connected between the commonly connected p-terminals and n-terminals, respectively.

In some embodiments, the reduced phonon conduction associated with the present embodiments of the thermoelectric devices (100) facilitates a more efficient thermoelectric system (200) for power generation than conventional thermoelectric systems. In other embodiments, the reduced phonon conduction associated with the present embodiments of the thermoelectric devices (100) facilitates a more efficient thermoelectric system (200) for heat dissipation or transport (i.e., cooling) than conventional thermoelectric systems.

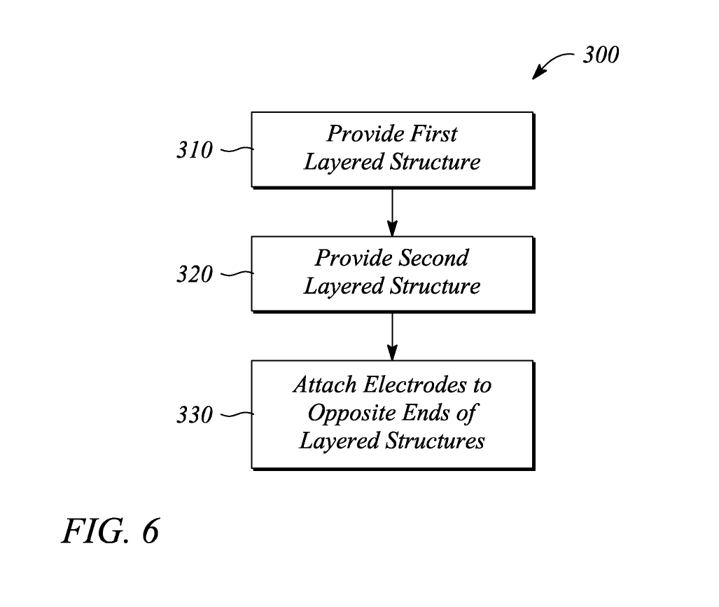

FIG. 6 illustrates a flow chart of a method (300) of making a thermoelectric device, according to an embodiment of the present invention. The method (300) of making a thermoelectric device comprises providing 310 a first layered structure comprising a p-type doped semiconductor material bounded by a second material and providing 320 a second layered structure comprising an n-type doped semiconductor material bounded by another second material. The respective doping of the first structure and the second structure provides high carrier conductivity. The first layered structure and the second layered structure are provided (310, 320) in a spaced apart relationship. The respective second materials are different materials from the respectively doped semiconductor material. The second material is provided as a layer of material that bounds the respectively doped semiconductor on at least one side in some embodiments, at least two sides in some embodiments, or surrounds the semiconductor in other embodiments. In some embodiments, the layers are planar layers. In some embodiments, the respectively doped semiconductor material is provided as a nanowire core and the respective second material is provided as a concentric layer that surrounds the nanowire core. The respectively doped semiconductor material independently has a thickness configured to be less than a phonon scattering length while being greater than a charge carrier scattering length.

The method (300) further comprises attaching (330) a common electrode to one end of both the first structure and the second structure and a pair of separate electrodes to an opposite end of the respective structures. A first electrode of the pair of separate electrodes is attached (330) to the opposite end of the first structure and a second electrode of the pair of separate electrodes is attached (330) to the opposite end of the second structure. The common electrode at one end of the provided (310, 320) structures and the separate electrodes at the opposite end establish a charge carrier conduction path through the structures. Moreover, the boundaries or interfaces between the respectively doped semiconductor material and the respective second material of each provided (310, 320) structure are parallel to the charge carrier conduction path.

In some embodiments, providing (310, 320) the first structure and the second structure independently comprises depositing planar layers of the respectively doped semiconductor material and the second material in a stack. The different materials alternate regularly in the stack. In some embodiments, a third material that is different from the respectively doped semiconductor material and the second material is deposited as a planar layer in the stack. In some of these embodiments, the different materials alternate regularly in the stack and in other embodiments, the different materials alternate irregularly in the stack. In either case, the respectively doped semiconductor material layer is an ultra thin film bounded on one side or opposite sides by one or both of the second material and the third material. In some embodiments, the provided (310, 320) first and second structures are substantially similar to the first and second structures (110, 120) described above with respect to the thermoelectric device (100) and thermoelectric system (200).

In some embodiments, providing (310, 320) the first structure and the second structure further comprises depositing an insulator spacer layer between the stack of material layers of the first structure and the stack of material layers of the second structure to space apart the first and second structures. The insulator spacer layer is one to several or more orders of magnitude thicker than the thickness of the respectively doped semiconductor layer of a respective structure.

In some embodiments, forming the stack comprises depositing a planar layer of a second material (e.g., SiO₂) having a thickness in the tens of nanometers. On the exemplary SiO₂ planar layer, a planar layer of the first material (e.g., a polycrystalline Si (poly-Si) film) is deposited also having a thickness in the tens of nanometers. The exemplary poly-Si film is p-doped, for example. Alternating planar layers of the SiO₂ and the p-doped poly-Si are repeated multiple times to form a stack that becomes the p-type structure.

In some embodiments, growth of the stack is continued to form the n-type structure by first forming a very thick planar layer of an insulator spacer material (e.g., SiO₂) on the last p-doped poly-Si planar layer. The very thick layer of the exemplary SiO₂ insulator material is one to several or more orders of magnitude thicker than the poly-Si film layer, e.g., hundreds of nanometers thick. On the very thick layer of SiO₂, a planar layer of an n-doped first material (e.g., poly-Si) is deposited having a thickness in the tens of nanometers, followed by a planar layer of a second material (e.g., SiO₂) in the tens of nanometers. Alternating planar layers of the exemplary SiO₂ and exemplary n-doped poly-Si are repeated multiple times on the stack to form the n-type structure stacked on the p-type structure. In this embodiment, the multiple deposition steps to form the stack of alternating planar layers that form the oppositely doped structures may be performed in a single chemical vapor deposition (CVD) chamber.

In some embodiments, one or more of the thin planar layers of the second material may be another material, for example polycrystalline Ge that is respectively p-doped or n-doped instead of the planar layer of the exemplary SiO₂. Moreover, in some embodiments, one or more thin planar layers of the first material (the exemplary poly-Si) may be patterned into spaced apart elongated stripes during fabrication. The elongated stripes extend from one end of the stack to the opposite end of the stack in a common plane.

In some embodiments, the stack of alternating planar layers is diced into multiple layered pieces, each layered piece comprising both a p-type structure and an n-type structure separated by relatively very thick the insulator spacer. Each layered piece has a length ranging from about 1 micrometer (microns or μm) to about several millimeters (mm) long, for example. In some embodiments, the layered pieces are about 100 microns to about 1 mm long. In some embodiments, opposite ends of the layered pieces are polished such that ends of the respectively doped semiconductor layers are exposed.

A layered piece is then assembled into a thermoelectric device. In some embodiments, a pair of spaced apart separate electrodes is formed on a surface of a substrate, for example by sputtering or evaporation of a metal including, but not limited to, gold, silver, copper or aluminum. The spacing of the separate electrodes corresponds to the thickness of the insulator spacer of the layered pieces. One end of the layered piece is aligned to the separate electrodes such that the p-type structure side is aligned to one of the electrodes of the pair and the n-type structure side is aligned to the other electrode of the pair. The aligned piece is attached (330) to the pair of separate electrodes such that an electrical connection between the respective separate electrode and the layers of the respectively doped semiconductor first material is formed (i.e., electrically attached). For example, a conductive epoxy, solder or another attachment technique may be used to attach (330) the end of the layered piece to the pair of separate electrodes. The common electrode is attached (330) to an opposite end of the layered piece, for example, by directly depositing a metal on the opposite end using sputtering or evaporation. Alternatively, the common electrode may be formed on the surface of the substrate or the common electrode itself is the substrate. The layered pieces are connected to the common electrode and then a separate electrode is formed on each of the p-type structure and the n-type structure to attach (330) the respective electrodes.

In another embodiment, both ends of the layered piece may be directly coated with the respective electrodes (in attaching (330) the electrodes according to the method 300). For example, at one end of the layered piece, each respectively doped structure may be coated with a metal, spaced apart by the thickness of the insulator spacer, to form the separate electrode pair directly on the layered piece. The common electrode may be formed directly on the opposite end of the layered piece bridging between the respectively doped structures. In another embodiment, one end of the diced layered pieces may be selectively etched to expose the respectively doped first material layers of each structure, for example. Then the ends of each structure may be metalized to make separate electrodes. The opposite end of the diced pieces may be selectively etched to expose the respectively doped first material layers, for example, and then the opposite end is metalized to form the common electrode (in attaching (330) the respective electrodes according to the method 300).

In other embodiments, providing (310) the first structure comprises forming a plurality of nanowire cores of the p-doped semiconductor material on a surface. Moreover, providing (320) the second structure comprises forming a plurality of nanowire cores of the n-doped semiconductor material spaced apart from the first structure on the surface. In some embodiments, the respective plurality of nanowire cores are formed using a nanowire growth technique such as vapor-liquid-solid (VLS) growth or a similar technique that includes using a nanoparticle catalyst. After the nanowire cores are grown, the nanoparticle catalyst may be removed from the free ends of the nanowire cores. The nanowire cores are respectively doped either during or after they are formed. In some embodiments, the nanowires may be about 1 micron long to about 100microns long. In some embodiments, the nanowires may be about 5 microns long to about 20 microns long.

Providing (310, 320) the first structure and the second structure independently further comprises providing a concentric layer of the second material on the nanowire cores. The concentric layer of the second material coaxially bounds the nanowire core and forms a core-shell nanowire having a boundary between the core material and the shell material that extends the length of the nanowire core. For example, the second material may be epitaxially grown on the nanowire core.

In some embodiments, providing (310, 320) the first structure and the second structure independently further comprises planarizing the free ends of the core-shell nanowires until both the nanowire core and the shell layer are exposed at the free ends. Before planarization, the core-shell nanowires are embedded in a matrix material that is hardened or cured to prepare the core-shell nanowires for planarization. For example, a chemical mechanical polishing (CMP) technique may be used. In some embodiments, providing (310, 320) the first structure and the second structure independently further comprises exposing the core-shell nanowires to a thermal treatment that produces diffused interfaces. For example, the first material (of the core) may comprise silicon (Si), and the second material (of the shell) may comprise germanium (Ge) of the core-shell nanowires. Thermal annealing at sufficient temperatures induces intermixing of the Si and Ge to form a third phase, SiₓGe₁₋ₓ, where 0<x<1 at the boundary, which further enhances scattering of phonons. For Si/Ge systems, a temperature of about 650° C. or about 700° C. is sufficient to cause diffusion, for example.

In some embodiments, providing (310, 320) the first structure and the second structure independently further comprises providing an outer concentric layer on the second material concentric layer before planarizing the free ends. In some embodiments, the nanoparticle catalyst is removed prior to providing the outer concentric layer. The outer concentric layer comprises a third material that is different from the second material, and in some embodiments, is different from the nanowire core material. The third material bounds the second material. The second material layer becomes an intermediate shell layer and the third material layer forms an outer shell layer. The outer shell layer provides an additional parallel boundary between different materials along the length of the nanowire. At least the core has a characteristic thickness (or diameter) that is greater than the charge carrier scattering length but less than a phonon scattering length.

In some embodiments, one or both of the second material and the third material is another semiconductor material different from the nanowire semiconductor core. In some of these embodiments, one or both of the second semiconductor material and the third semiconductor material is moderately to heavily doped with the respective doping type of the nanowire cores of the respective first structure and the second structure to provide high carrier conductivity. In some embodiments, one or both of the concentric shell layers further has a characteristic thickness that is greater than the charge carrier scattering length but less than a phonon scattering length.

In an example, the first structure and the second structure independently comprise germanium (Ge) nanowire cores having a intermediate shell layer comprising silicon (Si) and an outer shell layer comprising germanium (i.e., Ge/Si/Ge core-shell nanowires). The nanowires are grown using metallic nanoparticle catalysts, for example, starting with a germanium core, followed by either silicon or a silicon-rich SiGe alloy intermediate shell, which is followed by an outer shell of either germanium or a germanium-rich SiGe alloy, all in a single CVD chamber, for example. The nanowire core and the concentric shell layers are independently moderately to heavily doped with the respective p-type or n-type dopants either during forming the core-shell nanowires or after the core-shell nanowires are formed.

In some embodiments, the p-type core-shell nanowires may be grown directly on a surface of one of the separate electrodes of the pair to form the p-type structure directly attached (330) to the separate electrode while the n-type core-shell nanowires may be grown directly on a surface of the other of the separate electrodes of the pair to form the n-type structure directly attached (330) to the other separate electrode, for example. In some embodiments, the attachment between the core-shell nanowires and the respective separate electrodes is an epitaxial attachment (330). The pair of separate electrodes may be attached to a substrate either before or after growth of the core-shell nanowires, or the electrodes themselves are the substrate.

The core-shell nanowires are then embedded in an insulator matrix material that is hardened or cured and the free ends of the core-shell nanowires are planarized to expose the concentric layers of each core-shell nanowire. After planarization, a common electrode is then deposited or otherwise attached (330) to the planarized free ends of the core-shell nanowires such that the common electrode bridges across the p-type structure and the n-type structure. The coaxial boundaries between the respective materials of the core-shell nanowires are parallel to the charge carrier conduction path between the common electrode and the separate electrodes. In another embodiment, the core-shell nanowires for each structure may be grown on the common electrode in a spaced apart relationship and after embedding the nanowires and planarizing the free ends, the pair of separate electrodes are formed on the free ends to separately access the p-type structure and the n-type structure.

In some embodiments, a dense array of core-shell nanowires is provided for each of the p-type and n-type structures. The density of the nanowires may be determined by the total current targeted for the device. For example, a density of one nanowire per square micron may be applicable. In a dense array where the core and the concentric shell layers of the core-shell nanowires each has a diameter or shell thickness that does not exceed about 100 nm, for example, the phonon transport may be suppressed down to about 1-5 Watts/Kelvin-meter (W/K-m²) in some embodiments. On the other hand, the electrical conductivity may be very high, or correspondingly the electrical resistivity may be very low, for example in a milli Ohm-centimeter range. As such, in some embodiments, the dense array of core-shell nanowires may provide for very low electrical resistance of a thermoelectric device and system, while the interfaces or boundaries between the various shell layers of the core-shell nanowires will dramatically suppress thermal conductance. Moreover, in some embodiments, the core-shell nanowires are expected to have high quality interfaces between the core/shell and shell/shell layers. As such, only a moderate increase in electrical resistivity may be expected in some embodiments relative to bulk silicon or germanium, for example.

Thus, there have been described embodiments of a thermoelectric device, a thermoelectric system and a method of making a thermoelectric device that employ semiconductor layers having a thickness that is less than a phonon scattering length bounded by another material such that boundaries therebetween are parallel to a charge carrier conduction path between electrodes. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A thermoelectric device (100) comprising:
a common electrode (140);
a pair (150) of separate electrodes (150a, 150b); and
a pair of spaced apart oppositely doped structures (110, 120) connecting between the common electrode (140) at a first end and different ones of the separate electrodes (150a, 150b) at a second end of the structures (110, 120), each oppositely doped structure (110, 120) comprising a first material (112, 122) of a respectively doped semiconductor bounded by a second material (114, 124, 116, 126),
wherein boundaries (111, 121) between the respective first and second materials (112, 122; 114, 124, 116, 126) are parallel to a charge carrier conduction path between the common electrode (140) and the separate electrodes (150a, 150b), the respectively doped semiconductor (112, 122) having a thickness configured to be less than a phonon scattering length.

2. The thermoelectric device (100) of claim 1, wherein the respectively doped semiconductor first material (112, 122) and the second material (114, 124, 116, 126) are adjacent planar layers.

3. The thermoelectric device (100) of claim 2, wherein the respectively doped semiconductor layers of the first material (112, 122) layers independently comprise spaced apart elongated stripes in a common plane bounded on two sides by the second material (114, 124, 116, 126).

4. The thermoelectric device (100) of claim 2, wherein the respectively doped semiconductor layers of the first material (112, 122) independently comprises a polycrystalline semiconductor.

5. The thermoelectric device (100) of claim 1, wherein the second material is a concentric layer (114, 124, 116, 126) surrounding a nanowire core (112, 122) of a core-shell nanowire, the nanowire core (112, 122) comprising the respectively doped semiconductor first material.

6. The thermoelectric device (100) of claim 5, wherein the oppositely doped structures (110, 120) independently comprise a plurality of the core-shell nanowires extending from the common electrode (140) to the respective separate electrodes (150a, 150b), the core-shell nanowire comprising an intermediate shell layer of the second material (114, 124) surrounding the nanowire core (112, 122), and an outer shell layer (116, 126) of either the respectively doped semiconductor first material or a third material (116, 126) different from both the second material (114, 124) and the first material (112, 122).

7. The thermoelectric device (100) of claim 6, wherein the nanowire core material (112, 122) is germanium, the second material of intermediate shell layer (114, 124) comprising silicon, the third material of the outer shell layer (116, 126) comprising germanium.

8. The thermoelectric device (100) of claim 1, wherein the respectively doped semiconductor first material (112, 122) and the second material (114, 124, 116, 126) alternate in layers, a number of alternating material layers in a first structure (110) of the pair of oppositely doped structures being different from a number of alternating material layers in a second structure (120) of the pair of oppositely doped structures.

9. The thermoelectric device (100) of claim 1, wherein the second material (114, 124, 116, 126) of one or both of the structures (110, 120) of the pair of oppositely doped structures independently is an insulator.

10. The thermoelectric device (100) of claim 1, wherein the second material (114, 124, 116, 126) of one or both of the structures (110, 120) of the pair of oppositely doped structures independently comprises another semiconductor material that is different from the semiconductor first material (112, 122).

11. The thermoelectric device (100) of claim 1, further comprising a first mass (212) adjacent to the common electrode (140); a second mass (214) adjacent to the pair (150) of separate electrodes; and one of a resistive circuit and a voltage source connected between the pair (150) of separate electrodes (150a, 150b).

12. A thermoelectric system (200) comprising:
a plurality of pairs (100) of spaced apart oppositely doped structures (110, 120) connected together in series or parallel, each pair (100) connecting between a respective common electrode (140) at a first end and different separate electrodes (150a, 150b) at a second end of the structures (110, 120), each oppositely doped structure (110, 120) comprising a first material (112, 122) of a respectively doped semiconductor bounded by a second material (114, 124, 116, 126), wherein boundaries between the respective first and second materials are parallel to a charge carrier conduction path between the respective common electrode (140) and the separate electrodes (150a, 150b), the respectively doped semiconductor having a thickness configured to be less than a phonon scattering length;
a first mass (212, 214) adjacent to one of the common electrode (140) and the separate electrodes (150a, 150b);
a second mass (214, 212) adjacent to a different one of the common electrode (140) and the separate electrodes (150a, 150b); and
means (220) for sinking or sourcing energy connected between a p-type separate electrode (150a) of a first pair (100) of structures and an n-type separate electrode (150b) of an N-th pair (100) of structures of the plurality.

13. A method (300) of making a thermoelectric device comprising:
providing (310) a first layered structure comprising a p-type doped semiconductor bounded by another material;
providing (320) a second layered structure comprising an n-type doped semiconductor bounded by another material, the second structure being spaced from the first structure, the respectively doped semiconductors providing high carrier conductivity; and
attaching (330) a common electrode and separate ones of a pair of electrodes to opposite ends of the first structure and the second structure, wherein boundaries between the respective materials of the structures are parallel to a charge carrier conduction path between the common electrode and the respective separate electrodes, the respectively doped semiconductors independently having a thickness configured to be less than a phonon scattering length.

14. The method (300) of claim 13, wherein providing (310) a first layered structure and providing (320) a second layered structure independently comprises:
depositing planar layers of the respectively doped semiconductor material and the other material in a stack; and
forming an insulator spacer layer between stacks, wherein the respective other materials independently are one of a semiconductor material different from the respectively doped semiconductor material and an insulator material.

15. The method (300) of claim 13, wherein providing (310) a first layered structure and providing (320) a second layered structure independently comprises:
forming a plurality of nanowire cores of the respectively doped semiconductor material on a surface;
providing an intermediate concentric layer on the nanowire cores, wherein a material of the intermediate concentric layer comprises the other material; and
providing an outer concentric layer on the intermediate concentric layer to form core-shell nanowires, a material of the outer concentric layer being different from the intermediate concentric layer material.
